(19) United States
(12) Patent Application Publication
(10) Pub. No.: US 2026/0190938 A1
(43) Pub. Date: Jul. 2, 2026

(54) Controlling electrostatic discharge in a molding apparatus

(71) Applicant: CANON KABUSHIKI KAISHA, Tokyo (JP)

(72) Inventors: Yasaman Jahani, Pflugerville, TX (US); Edward Brian Fletcher, Austin, TX (US); Steven C. Shackleton, Austin, TX (US)

(21) Appl. No.: 19/004,051

(22) Filed: Dec. 27, 2024

(51) Int. Cl. H01L 21/683; G03F 7/00; H01L 21/67; H01L 21/687

(52) U.S. Cl. CPC H10P 72/722; G03F 7/0002; H10P 72/0428; H10P 72/7616

(57) ABSTRACT

A system is provided and includes a substrate chuck, and a second chuck configured to hold an object above the substrate chuck and one or more exhaust ports arranged adjacent to each of one or more electrostatic discharge diverter surfaces, wherein each of the one or more electrostatic discharge diverter surfaces are adjacent to the substrate chuck.

### TECHNICAL FIELD

The disclosure relates to controlling a system and method for preventing electrostatic discharge in in a molding apparatus.

### BACKGROUND

In nanoimprint lithography and inkjet adaptive planarization, the goal is to transfer a pattern of an imprint template to a corresponding field on a substrate. To achieve this, curable liquid resist is dispensed on the substrate and the template is caused to contact the substrate so that, after a curing process, the pattern on the template is transferred to a particular field on the substrate. In order to facilitate this process, forces are applied to the template by actuators in order to modify the template shape which helps reduce the difference in shape between the template and the substrate.

During the molding (also referred to as a planarizing, patterning or shaping) process, superstrates and substrates develop charged surfaces due to triboelectric charging during a separation phase where the mold and substrate are separated from one another. This occurs spontaneously and may result in transferring the charge to various hardware elements in the molding apparatus. Another issue resulting from this occurrence is that spark discharging may result in the formation of nanoparticles. Further, these nanoparticles may end up deposited on various object surfaces such as the superstrate, the substrate or other surfaces therearound inside the molding apparatus. In the case where these nanoparticles are formed and deposited, defects in the coatings may occur. Therefore, it is desirable to minimize the negative impacts resulting from spontaneous electrostatic discharge in a molding apparatus.

The molding process describes the shaping of a film on a substrate by the formation of a relief pattern in a formable material (polymerizable) layer. The shape of this film may then be used to transfer a pattern corresponding to the relief pattern into, onto, or into and onto an underlying substrate.

The shaping process uses a mold spaced apart from the substrate. The liquid imprint material is applied onto the substrate. The mold is brought into contact with the liquid imprint material that may have been deposited as a drop pattern using the liquid imprint material to spread and fill the space between the mold and the substrate. The formable liquid is solidified to form a film that has a shape (pattern) conforming to a shaping surface of the template. After solidification, the mold is separated from the solidified layer such that the mold and the substrate are spaced apart. The mold may be featureless and the solidified layer can be a planarization layer.

The substrate and the solidified layer may then be subjected to known steps and processes for device (article) fabrication, including, for example, curing, oxidation, layer formation, deposition, doping, planarization, etching, formable material removal, dicing, bonding, and packaging, and the like. For example, the pattern on the solidified layer may be subjected to an etching process that transfers the pattern into the substrate.

### SUMMARY

According to the present disclosure, a system is provided and includes a substrate chuck, and a second chuck configured to hold an object above the substrate chuck and one or more exhaust ports arranged adjacent to each of one or more electrostatic discharge diverter surfaces, wherein each of the one or more electrostatic discharge diverter surfaces are adjacent to the substrate chuck.

The details of one or more implementations of the subject matter described in this specification are set forth in the accompanying drawings and the description below. Other potential features, aspects, and advantages of the subject matter will become apparent from the description, the drawings, and the claims.

### DESCRIPTION OF DRAWINGS

FIG. 1 depicts a side view of a nanoimprint lithography system.

FIG. 2 depicts a top view of the substrate and applique having an electrostatic discharge diverter portion.

FIG. 3 is a table of materials that are usable for an electrostatic discharge diverter surface.

FIG. 4 is a table of materials that are usable for an electrostatic discharge diverter surface.

FIG. 5 is a cross section view of FIG. 2

FIG. 6 is an expanded view of a diverter illustrated in FIG. 5.

FIG. 7 depicts a top view of the substrate and applique having an electrostatic discharge diverter portion.

FIG. 8 is an expanded view of a diverter illustrated in FIG. 7.

FIG. 9 is a cross section view of FIG. 7.

FIG. 10 is an expanded view of a diverter illustrated in FIG. 7.

FIG. 11 is a flow diagram detailing the steps for manufacturing an article using the electrostatic discharge diverter.

Throughout the figures, the same reference numerals and characters, unless otherwise stated, are used to denote like features, elements, components or portions of the illustrated embodiments. Moreover, while the subject disclosure will now be described in detail with reference to the figures, it is done so in connection with the illustrative exemplary embodiments. It is intended that changes and modifications can be made to the described exemplary embodiments without departing from the true scope and spirit of the subject disclosure as defined by the appended claims.

### DETAILED DESCRIPTION

Embodiments will be described in detail below with reference to the accompanying drawings. The following embodiments are not intended to limit the claimed features. Although a plurality of features are described in the embodiment, not all of the plurality of features are essential, and the plurality of features may be combined or omitted depending on the circumstances. Further, in the accompanying drawings, the same reference numerals are assigned to the same or similar structures, and redundant explanations are omitted.

In this specification and the accompanying drawings, unless otherwise stated, directions are shown in an XYZ coordinate system in which the direction parallel to the surface of the substrate is the XY plane. The directions parallel to the X axis, the Y axis and the Z axis in the XYZ coordinate system are defined as the X direction, the Y direction and the Z direction, and the rotation around the X axis, the rotation around the Y axis and the rotation around the Z axis are defined as θX, θY and θZ, respectively. Control or drive with respect to the X-axis, the Y-axis and the Z-axis means control or drive with respect to a direction parallel to the X-axis, a direction parallel to the Y-axis and a direction parallel to the Z-axis, respectively. Control or drive of the θX, θY, and θZ axes means control or drive of rotation about an axis parallel to the X axis, rotation about an axis parallel to the Y axis, and rotation about an axis parallel to the Z axis, respectively. The position is information that can be specified based on the coordinates of the X, Y, and Z axes, and the posture is information that can be specified by the values of the θX, θY, and θZ axes.

A molding apparatus according to the present disclosure is an apparatus that performs a molding process for molding a composition on a substrate using a mold. Examples of the molding apparatus include an imprint apparatus and a planarizing apparatus. An imprint apparatus is an apparatus for forming (transferring) a pattern on a composition (imprint material) on a substrate by bringing a mold having a concavo-convex pattern into contact with the composition. The molding process performed in the imprint apparatus may be referred to as an imprint process. The planarizing device planarizes the surface of a composition on a substrate by bringing a mold having a flat surface into contact with the composition. The forming process performed in the planarizing apparatus may be referred to as a planarizing process. Hereinafter, an imprint apparatus will be described by way of example as a molding apparatus, but the construction and processing of the imprint apparatus can also be applied to a planarizing apparatus. In an alternative embodiment, there is a single field on the substrate that covers most of the substrate. In the following the terms template, superstrate, and mold are all substantially equivalent in the context of the present application.

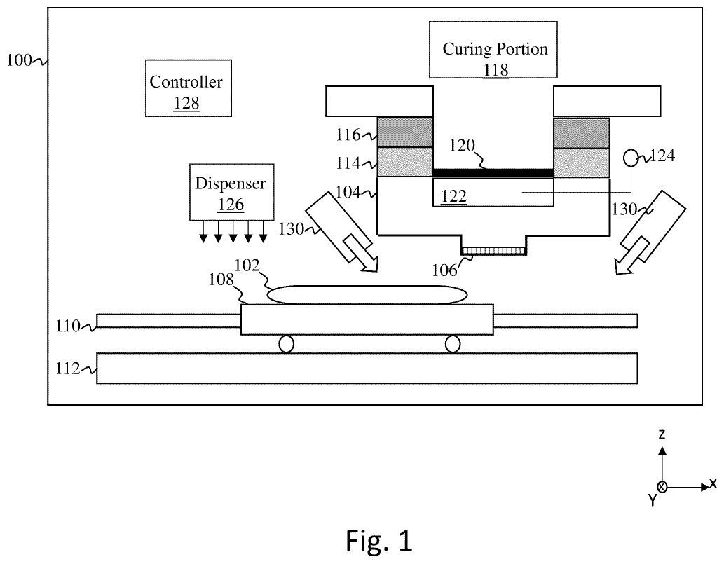

FIG. 1 is a schematic diagram showing a configuration example of an imprint apparatus/mold apparatus 100 according to the present embodiment. The imprint apparatus 100 is a lithographic apparatus for molding an imprint material (composition) on a substrate 102 using a mold 104, and can be employed in a lithographic process that is a process for manufacturing a magnetic storage medium, a semiconductor device, or the like. The imprint apparatus 100 brings an uncured imprint material supplied on the substrate 102 into contact with a mold 104, and gives energy for curing to the imprint material, thereby performing processing to form a pattern of a cured product on the substrate 102 onto which the pattern of the mold 104 is transferred. Such processing is called imprint processing, and is performed on each of a plurality of shot regions (imprint regions) on the substrate 102. In this embodiment, an example of employing a photocuring method in which the imprint material on the substrate 102 is cured by irradiating the imprint material with light (ultraviolet light) will be described. Throughout this disclosure the mold 104 may also be referred to as a superstrate 103. As such, these terms may be used interchangeably to describe this aspect of the apparatus.

Here, the mold 104 and the substrate 102 may be interchangeable, and the imprint material arranged on the mold 104 may be brought into contact with the substrate 102 to form (transfer) a pattern of the mold 104 on a film of the imprint material filled in a space between the mold 104 and the substrate 102. Thus, more generally, the imprinting device 100 is a molding apparatus that forms a pattern on a composition on a second member by curing the composition with the first member in contact with the composition on the second member and separating the first member from the cured composition. The imprint apparatus 100 performs a film forming process (film forming step) for forming a film of the composition on which the pattern of the first member is transferred, on the second member. In the present embodiment, an example will be described in which the first member is the mold 104 and the second member is the substrate 102, but the first member may be the substrate 102 and the second member may be the mold 104, in which case the mold 104 and the substrate 102 in the following description may be replaced with each other.

In certain embodiments, the mold 104 is formed from a material capable of transmitting light (ultraviolet light) therethrough, such as quartz glass. The mold 104 used in the imprint apparatus 100 has a pattern region 106 formed in a mesa shape having a step of, for example, several tens nm. A surface (pattern surface) on the substrate side of the pattern region 106 has a concave-convex pattern such as a circuit pattern to be transferred to the imprint material on the substrate 102, and functions as a molding surface (contact surface) for molding the imprint material in contact with the imprint material on the substrate 102. In the mold 104 used in the planarizing apparatus, 90% or more (preferably 95% or more) of the molding surface (contact surface) which is in contact with the composition on the substrate and forms the composition is formed as a flat surface on which no uneven pattern is formed.

The substrate 102 may be formed from materials that can having pattern formed thereon and include, but are not limited to glass, ceramics, metals, semiconductors, resins and the like. In certain embodiments, a member made of a material different from that of the substrate 102 may be provided on (or otherwise deposited on to) the surface of the substrate 102. In other embodiments, the substrate 102 may be, for example, a silicon wafer, a compound semiconductor wafer, quartz glass, or the like.

As the imprint material, a photocurable composition (sometimes referred to as an uncured resin) which is cured by having energy of a predetermined wavelength applied thereto resulting in the curing of the composition. Exemplary types of energy applied for curing operation include but are not limited to electromagnetic waves, heat and a combination thereof. In a case where the energy applied is electromagnetic waves, for example, the light may be selected from a wavelength range of 10 nm to 1 mm, for example, infrared light, visible light, ultraviolet light, and the like.

The imprint apparatus 100 includes a stage 108 (including a substrate chuck) that holds or otherwise supports and moves a substrate 102, a substrate driving mechanism 110 for driving (or otherwise moving) the substrate 102 by driving the stage 108, and a support base 112 that supports the substrate driving mechanism 110. The imprint apparatus 100 further includes a mold chuck 114 for holding the mold 104 (also referred to herein as an object), and a mold driving mechanism 116 for driving the mold 104 by driving the mold chuck 114. The mold chuck 114 may be, but is not limited to one or more of: vacuum chuck; pin-type chuck; groove-type chuck; electrostatic chuck; electromagnetic chuck; and other similar chuck types.

The substrate driving mechanism 110 can be configured to drive the substrate holding section with the substrate 102 about a plurality of axes (For example, three axes of an X axis, a Y axis, and a θZ axis, preferably six axes of an X axis, a Y axis, a Z axis, a θX axis, a θY axis, and a θZ axis) by driving the stage ST about the plurality of axes. The mold driving mechanism 116 may be configured to drive the mold chuck 114 and the mold 104 about a plurality of axes (For example, three axes of Z axis, θX axis and θY axis, preferably six axes of X axis, Y axis, Z axis, θX axis, θY axis and θZ axis) by driving the mold chuck 114 about the plurality of axes.

The substrate driving mechanism 110 and the mold driving mechanism 116 may operate as a relative driving mechanism for relatively driving the substrate 102 and the mold 104 so that the relative positions of the substrate 102 and the mold 104 are adjusted with respect to one another. Adjustment of the relative position by the relative drive mechanism may include driving for contact of the imprint material on the substrate 102 with the mold 104 and separation of the mold 104 from the cured imprint material. Adjustment of the relative position by the relative drive mechanism may also include alignment of the substrate 102 and the mold 104.

The imprint apparatus 100 may include a curing portion 118 for curing the imprint material filled in the space between the substrate 102 and the mold 104. The curing portion 118 may include an energy source that outputs energy to irradiate the imprint material on the substrate 102 with emitted energy (e.g., ultraviolet rays) through the mold 104 causing the imprint material to be cured. In some embodiments, the imprint apparatus 100 includes a transmission member 120 for forming a space 122 on the back side of the mold 104 (opposite to the surface facing the substrate 102). The transmission member 120 may be formed from a material that allows the energy emitted from the curing part 118 to permeate therethrough. The permeation of the curing energy emitted by the curing portion 118 enables irradiation of the to the curable composition on substrate 102. The curing portion 118 can be arranged to irradiate the imprint material while the mold chuck is holding the mold or while the mold chuck is no longer holding the mold.

The imprint apparatus 100 may also include a pressure controller 124 for controlling the deformation of the mold 104 in the Z-axis direction by controlling the pressure in the space 122. For example, when the pressure controller 124 sets the pressure in the space 122 higher than the atmospheric pressure, the mold 104 can be deformed into a convex shape toward the substrate 102.

The imprint apparatus 100 may include one or more dispensers 126 which serve as liquid supply source. The dispensers 126 supply, arrange, or dispense the liquid imprint material in direction illustrated by arrows extending therefrom in a direction towards the substrate 102. The liquid dispensed by dispensers 126 are dispensed as a plurality of droplets on the substrate 102.

The imprint apparatus 100 may include a controller 128 that controls all operational aspects of the imprint device 100 in order to achieve the imprint process. The control unit 128 includes a computing device that includes one or processor more processors such as a CPU (Central Processing Unit) and a storage unit such as a memory. The control unit 128 controls the imprint processing by controlling each component of the imprint apparatus 100 based on a computer program (e.g. computer executable instructions that, when executed configure the one or more processors to perform the instructions) stored in a storage unit (memory) as a storage medium.

The imprint apparatus 100 sequentially performs imprint processing on each of one or more shot regions on the substrate 102. In the imprint processing, first, the substrate 102 is arranged below the dispenser 126 by driving the stage 108 by the substrate driving mechanism 110. The imprint material is supplied from the dispenser 126 onto the substrate 102 and performs a liquid supply operation. When the liquid supply operation is completed, the stage 108 is driven by the substrate driving mechanism 110 to arrange the substrate 102 below the mold 104. In an alternative embodiment, the dispensing may be done at a separate station and loaded onto the substrate chuck with liquid material already dispensed onto it. Then, the mold 104 is driven in the −Z direction by the mold driving mechanism 116, whereby the pattern region 106 (pattern surface) of the mold 104 is brought into contact with the imprint material on the substrate 102 (contact operation). In a state where the mold 104 and the imprint material on the substrate 102 are in contact with each other, the substrate 102 and the mold 104 are aligned, and then the imprint material is cured by the curing part 118 (curing operation). In an alternative embodiment, the mold is released from the mold chuck 114, the imprint material is cured, and then the mold is reacquired by the mold chuck 114. Thereafter, the mold 104 is driven in the +Z direction by the mold driving mechanism 116 to separate the mold 104 from the cured imprint material on the substrate 102 (mold release operation). As a result, a pattern corresponding to the pattern from the pattern region 106 of a cured imprint material can be formed on the substrate 102. In an embodiment, the pattern is featureless and the cured imprint material forms a planarized film.

Further, in the imprint apparatus 100, as shown in FIG. 1, a gas supply 130 (nozzle) for supplying a gas is provided. The gas supplied by gas supply 130 can be a gas, such as helium, carbon dioxide, etc., that reduces non-fill defects and/or is a discharge reducing gas (helium. ionized gas, humidified gas) that reduces (inhibits) a discharge phenomenon from and around the mold 104 whereby electrostatic discharge occurs and potentially results in the formation of nanoparticles on any of the surfaces in the imprint apparatus 100 that have described herein. Examples of the discharge reducing gas include ionized air or helium. In some embodiments, the gas supply 130 is an alpha emitter which is caused, by the controller 128, to emit ionized air therefrom during the unloading stage when the substrate 102 is being unloaded from the stage 108. In the embodiment shown herein, the gas supply 130 is positioned and aimed such that the gas is provided in a direction towards the substrate 102 (−Z direction). However, this is merely exemplary, the gas supply 130 may also be positioned such that the gas output by the gas supply 130 is output in a direction towards the mold 104 (+Z direction). In another embodiment, a first gas supply 130 supplies gas in a direction towards the substrate 102 and a second gas supply 130 supplies gas in a direction towards the mold 104 in order to provide ionic air in a gap between the substrate 102 and mold 104 when they separate from one another. The gas supply 130 can supply multiple types of gases, e.g., inert gas (nitrogen), permeable gas (helium), condensable gas (PFP), ionizing gas, stripping gas, active gas, temperature controlled gas (air), humidity may contain a conditioned gas (air).

It is the object of the present disclosure to further reduce (or inhibit) negative impacts resulting when nanoparticles are formed due to the spontaneous electrostatic discharge that may occur during separation processing whereby the substrate 102 having the cured imprint thereon is separated from the mold 104 as described herein. More specifically, when the substrate (e.g. wafer) moves to an unload position, the uncontrolled discharge of charged particles occurs between the charged coating on the pattern region 106 and all surrounding hardware resulting in the surrounding hardware being sputtered with charged particles generated during the spontaneous electrostatic discharge event. When the charged particles contact the surfaces of the surrounding hardware, nanoparticles can be formed and output from the sputtered hardware to any other surface such as the coating on the pattern region 106 of the mold 104. This is problematic because, in subsequent imprint processing operations, the pattern region 106 is deformed due to the various nanoparticles on it. This would result in an erroneous imprint processing on subsequent substrates due to the presence of the nanoparticles on the pattern region 106 disrupting the proper pattern transfer to the substrate 102. While the description of the errors caused by the sputtered nanoparticles attaching to the pattern region 106, it should be noted that this may also occur in case where there are charged portions or liquids present on the substrate as well.

More specifically, electrically insulating portions of the stage 108 do not become substantially charged during separation of the substrate 102 from the mold 104. But, as the stage drive mechanism 110 is controlled by a control signal provided by the controller 128 to move the substrate 102 to an unload position, the metal hardware (electrically conductive portion) of the stage 108 that surrounds the substrate 102 is caused to pass underneath the charged pattern region 106 of the mold 104. As used herein, the mold 104 is a superstrate and the pattern region 106 is a superstrate coating region that is charged. Because of the position of the gas supply 130, it is possible for electrostatic discharge event to occur with the electrically conductive portions of the hardware that forms the stage 108 before the stage hardware 108 reaches a region covered by ionized gas supplied from an ionizer (e.g. ionized air from the alpha emitter) such that a sufficient ion density is not generated prior to the stage drive mechanism 110 moving the stage 108 into the unload position.

The generated nanoparticles being metal can be attracted to the charged coating on the mold/template/superstrate (pattern region 106). These nanoparticles are sputtered from the stage hardware 108 and can have an energy that causes these nanoparticles to bury into the coating on the pattern region 106. Thus, in the next planarization (imprint process), the nanoparticle can be further embedding into the coating on the pattern region 106 and also may extend outward from the pattern region and contact the liquid dispensed on the substrate 102 by the dispenser 126. This is particular problematic because the nanoparticles may be dislodged during subsequent planarization leaving a cavity in the pattern region 106 and also causing spheroid defects on the subsequent imprinted substrate 102. This defect is exacerbated with each subsequent planarization operation.

According to the present disclosure, the imprint apparatus 100 includes a hardware diverter that controls and facilitates where electrostatic discharge events can occur by creating favorable conditions for discharge at the intended locations and also provides a discharge port that enables discharge of any nanoparticles that might be formed in a case where electrostatic charges do contact the hardware in the apparatus. The diverter advantageously includes a conductivity section that is highly conductive relative to other nearby hardware thereby increasing the likelihood of attracting charged particles and particle collection port through which any generated nanoparticles can be removed. The conductivity section promotes discharge and the particle collection port removes, from the environment, a nanoparticle which can be sputtered in order to prevent the nanoparticles from traveling to the mold, substrate, or other surfaces inside the tool.

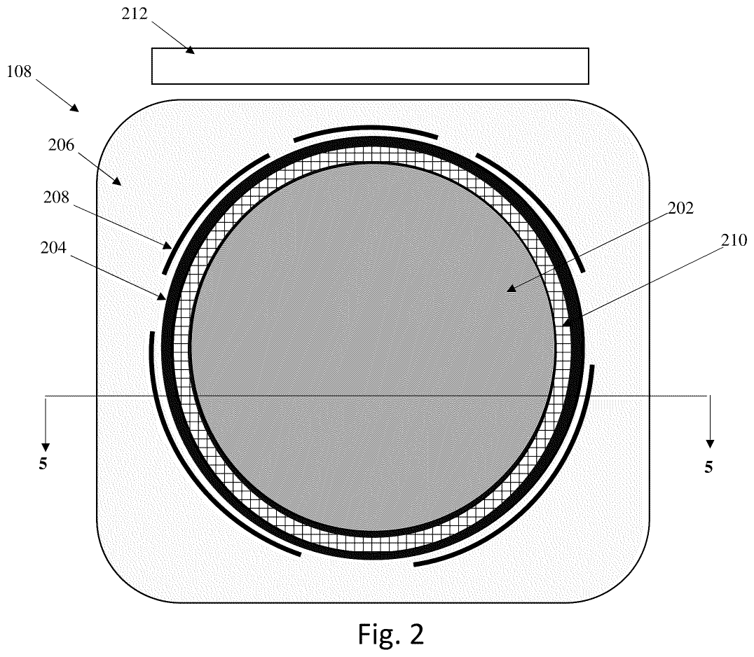

FIG. 2 illustrates a top view of the stage as shown in FIG. 1 with a diverter section included therein that functions to divert any electrostatic discharge that occurs and also attracts and eliminates any nanoparticles which are caused by electrostatic discharge that was not diverted. As shown herein an exemplary stage 108 according to the present disclosure includes a substrate chuck 202 that positioned at substantially a central position of the stage 108 and is also known as chuck and supports the substrate 102 (FIG. 1) on which imprinting occurs. The substrate chuck 202 may be, but is not limited to, one or more of: a vacuum chuck; pin-type chuck; groove-type chuck; electrostatic chuck; electromagnetic chuck; and the like. The imprint apparatus 100 may have a support ring 204 to which the substrate chuck 204 is attached. A support ring 204 is positioned concentrically outward from the substrate chuck 202 and is known as the chuck ring. An outer support section 206 is located concentrically outward from the support ring 204. The outer support section 206 is known as the applique. Both the support ring 204 and outer support 206 can be formed from insulating materials. The description of the support ring 206 and outer support 208 are described separately for purposes of example only and the support ring 206 and outer support 208 may be formed as a single element and not two separate elements.

A plurality of as inlets 208 extend through the outer support 206 and provide an inlet for gas to be provided into the region between the stage 108 and the mold 104. In one embodiment, the plurality of gas inlets 208 provide a pathway for purging gas (for example helium or carbon dioxide) to flow into the region between the stage 108 and mold 104 as shown in FIG. 1. The purpose of the purging gas is to prevent oxygen from poisoning the liquid imprint material prior to curing. Some liquid imprint materials can be sensitive to the presence of oxygen. The purging gas may also have the property of high diffusivity through the substrate, mold, and/or imprint material. The plurality of gas inlets 208 can also supply a separation gas which may be the same or different from the purging gas.

A diverter 210 (electrostatic discharge diverter surface) is a section of the stage 108 that is positioned between an inner edge of the support ring 204 which contacts the support section 204 and the outer support region 206. The diverter 210 extends through the support ring 204 and includes at least one channel and a diversion material that is grounded. As shown herein, the diverter 210 extends around an entire circumference of the substrate support 202 through the support ring 204. However, this is shown for purposes of example only. The diverter 210 may extend around only a portion of the substrate support 202. In other words, the diverter 210 may be semi-circular in shape and extend through the support ring 204 in a semi-circular pattern instead of the circular pattern shown in FIG. 2. In an embodiment, where the diverter 210 extends partially around the substrate support 202, the diverter 210 is positioned on a side of the substrate support 202 that is most proximate to the alpha emitter 212 that emits ionic air into the imprint region from a stage-side location. For example, the diverter 210 may extend around a top side of the substrate support 202 when looking at the stage from a top view as is the case in FIG. 2. The diverter has an electrostatic diverter surface. The purpose of the diverter 210 is to supply a preferential electrical path for any electrostatic discharge event that might occur as the mold 104 travels from a separation position above the substrate chuck to above the alpha emitter 212 which is the preferred electrostatic discharge position supplied by the ionized gas produced by the alpha emitter.

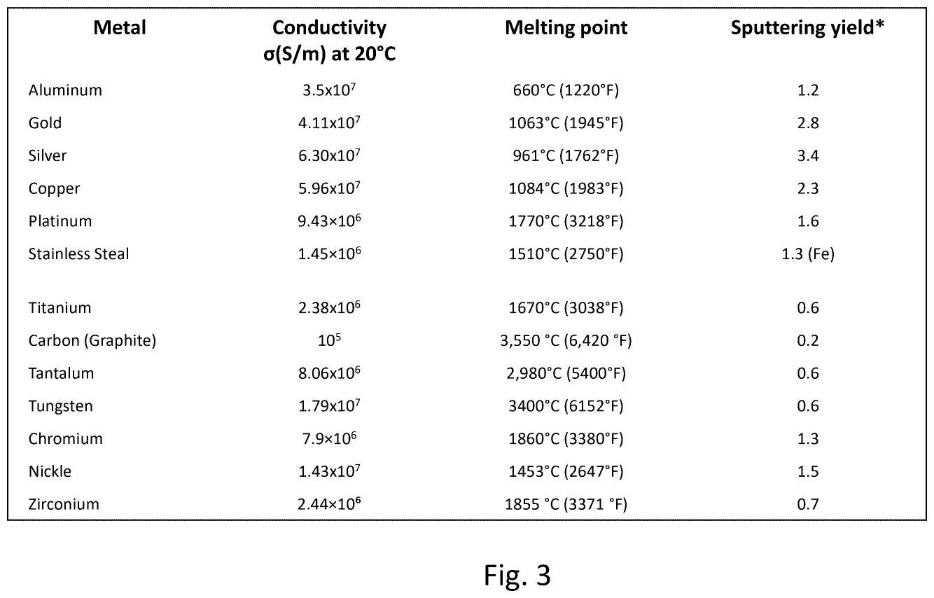

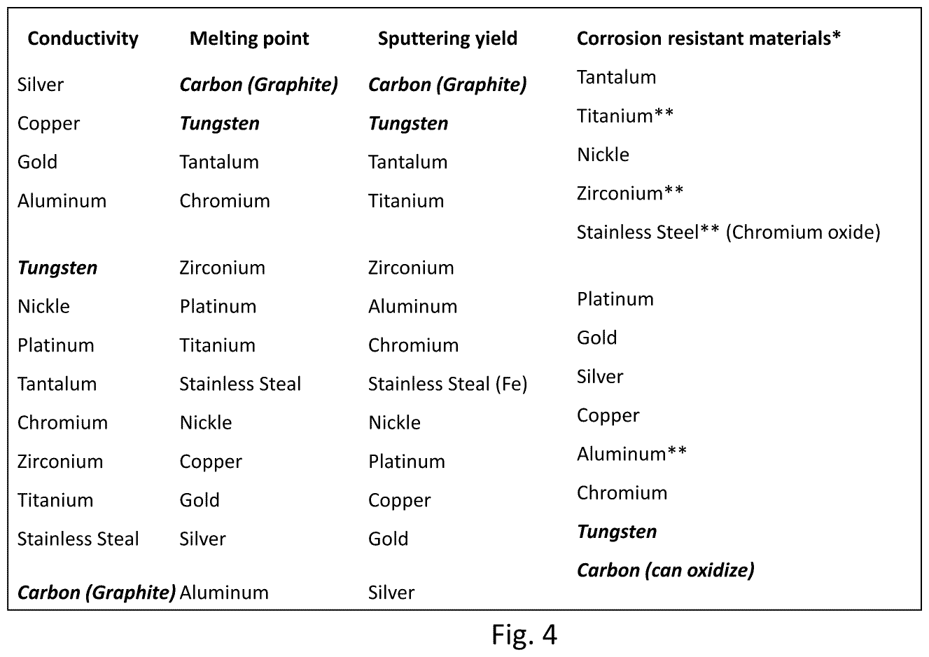

In an exemplary embodiment, the electrostatic discharge diverter surface 210 is a mesh. In the embodiment shown herein the diversion material is a mesh that is formed from a material that has one or more of: a high melting point, a low sputtering yield, corrosion resistant and is also highly conductive. Examples of high melting points are materials that melt at any of the following temperatures: 660° C.; 961° C.; 1063° C.; 1084° C.; 1453° C.; 1510° C.; 1670° C.; 1770° C.; 1855° C.; 1860° C.; 2,980° C.; 3,550° C.; and 3400° C. Examples of materials providing low sputtering yield are: 0.2; 0.5; and 0.7 atom per 600 eV argon atom. Examples of materials having high conductivity are those having a conductivity greater than 10⁵ S/m or at least 10 times the conductivity of the surrounding material. Exemplary materials that may be used in forming the diversion material mesh of the diverter 210 are illustrated in the table shown in FIG. 3. The table in FIG. 3 illustrates the numerical values of each of the properties considered when forming the diversion material. FIG. 4 includes table that ranks each of the materials relative to one another based on the numerical values illustrated in FIG. 3. In FIG. 4, certain materials such as carbon (graphite) and tungsten meet the requisite material requirement for use in forming the mesh that forms part of the diverter 210. In certain embodiments, the materials that form the electrostatic discharge diverter surface are coating materials that form an outer coat over an underlying surface material. In other embodiments, the materials the form the electrostatic discharge diverter surface are pure or otherwise entirely formed from that material. In other embodiments, the electrostatic discharge diverter surface is formed from an alloy of the material selected such that the alloy has all of the properties described hereinabove. In further embodiments, the material selected for the electrostatic diverter surface covers only a portion of the surface thereby providing direct targets for the charges emitted during electrostatic discharge.

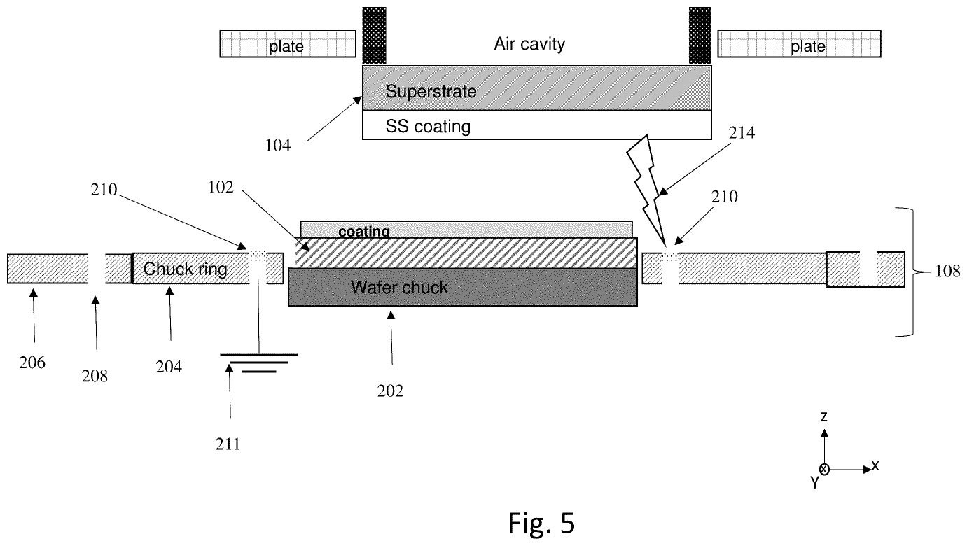

Also, as will be shown in more detail in FIG. 5, the mesh material covers an opening of the at least one channel of the diverter 210 such that the mesh section attracts the electrostatic discharge that may occur in the manner discussed above. The mesh also has openings of a size to allow for any nanoparticles that are inadvertently created to pass through the mesh and into the at least one channel so that they can be removed from the imprinting environment and not attach to the mold 104 or any other surfaces. The at least one channel of the diverted 210 can be connected to a vacuum line or a vacuum pump.

Additional features of the embodiment shown in the top view in FIG. 2 can be seen in FIG. 5 which represents a cross section of the stage 108 taken along the line labeled 5-5 in FIG. 2. The side view of the stage 108 in FIG. 5 also illustrates a substrate 102 being positioned atop the substrate chuck 202 that is held in place by the support ring 204 and outer support 206 and also includes the gas inlets 208 for supplying gas into the region between the mold 104 and the stage 108. The diverter 210 is grounded by an electrical connection to ground 211 and includes the diversion material (e.g. mesh) covering the at least one channel extending through the support ring 204. FIG. 5 illustrates a point in the imprint process whereby the mold (superstrate) 104 is separated from the substrate 102 after planarization (imprinting) of the coating thereon has occurred and the stage 108 is moving in an -X direction. It is during this process whereby an electrostatic discharge 214 event can occur and, if not diverted by diverter 210, could result in sputtering event that generate nanoparticles that would negatively impact the coating on the mold 104 for subsequent imprint operations.

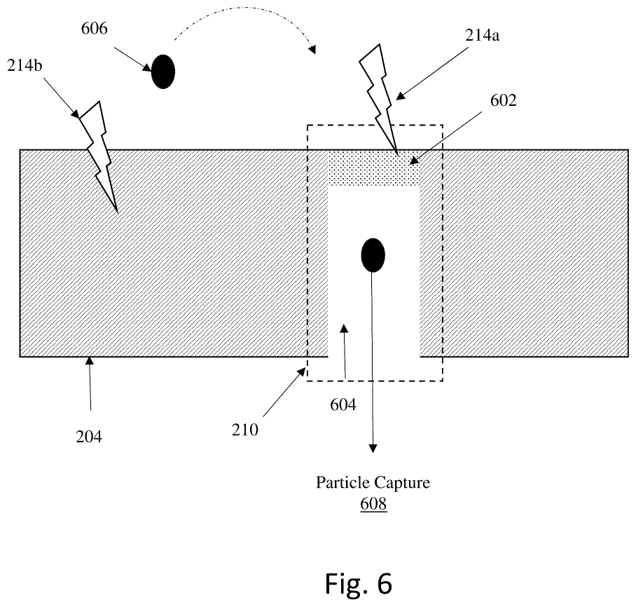

An enlarged view of the diverter 210 is illustrated in FIG. 6. The diverter 210 is shown in the dashed box in FIG. 6. The diverter 210 includes the diversion material 602 (e.g. conductive mesh) and the at least one channel 604 that extends through the support ring 204 and provide an exhaust port for any nanoparticles 606 to exit the imprint region and not be deposited onto the coating of the mold 104 shown in FIG. 5. In FIG. 5, electrostatic discharge 214a is attracted by the conductive diversion material 210 (mesh) that covers the at least one channel 604 that extends through the support ring 206. This advantageously minimizes the electrostatic discharge from contacting a surface of the support ring 206. In an ideal situation the diversion material 602 of the diverter 210 will attract all instances of electrostatic discharge and prevent formation of any nanoparticles, the diverter 210 further includes the at least one channel 604 through which any nanoparticles that is generated in the electrostatic discharge event can pass thereby removing them from the imprint environment. As shown herein, electrostatic discharge 214b was not captured by the mesh 602 and contracts a surface of the support ring 206. And, while the support ring 206 is formed from an insulated material, a nano particle 606 is sputtered into the gap between the stage 108 and the mold 104. By employing a particle capture mechanism 608 in communication with the at least one channel 604, the generated nanoparticle passes through the mesh 602 and into the at least one channel 604 to be removed. In one embodiment the particle capture mechanism 608 is a vacuum and is positioned on an underside of the stage 108. The particle capture mechanism 608 being positioned near each static discharge point includes using exhaust or vacuum to suck the nanoparticles from the local imprint environment, attract particles using charged plates, blowing a gas in a direction to direct a particle into the direction of a particle capture mechanism 608.

As shown herein, the diverter 210 includes a mesh cover section 602 formed from a material that has a high melting point and low sputtering yield such that fewer nanoparticles are generated when targeted by an electrostatic discharge event. Moreover, the mesh cover section 602 has a high conductivity level which increases the likelihood that the mesh cover section will be targeted by the electrostatic discharge because it provides an easier pathway for charge to flow. The conductivity of the mesh cover section 602 should have a higher conductivity as compared to all materials surrounding it such as the substrate chuck 202 and the support ring 204 and outer support 206. The mesh cover section 602 covers an opening of the at least one channel 604 a first side of the channel closest to the mold 104. A second side of the at least one channel, opposite the first side, includes the exhaust port through which any nanoparticles 606 can pass and be collected by the particle capture mechanism 608.

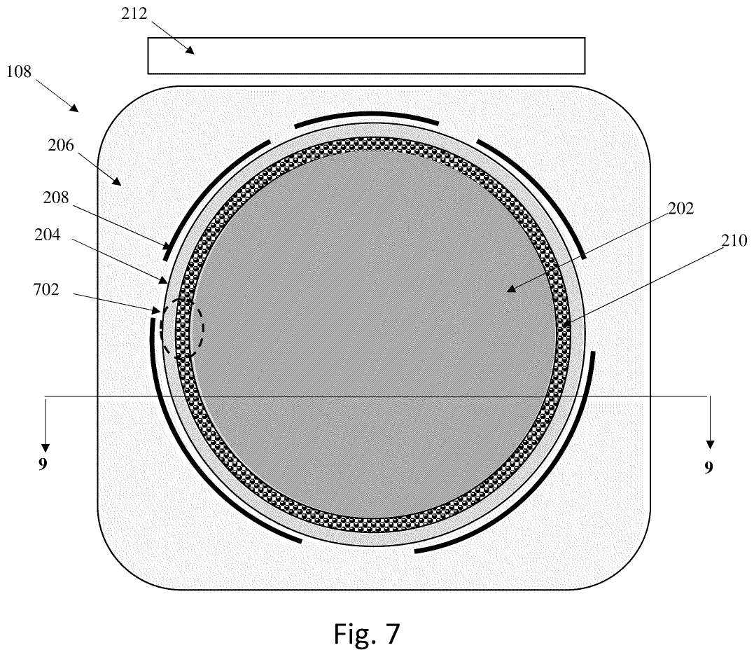

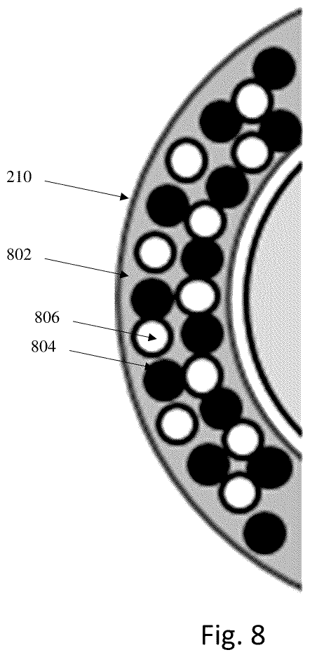

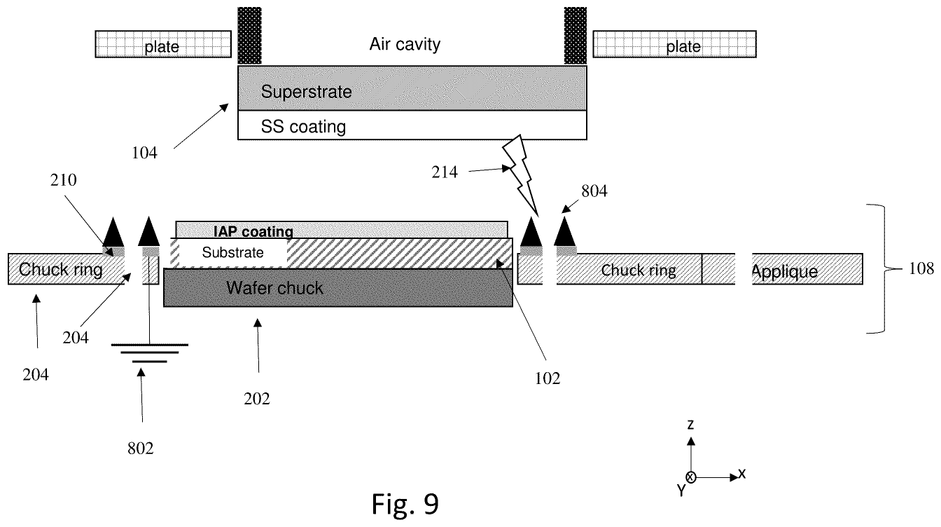

FIG. 7 illustrates another embodiment of the present disclosure. FIG. 7 is a top view of the stage 108 similar to the view shown in FIG. 2. All elements shown and described in FIG. 2 are labeled with the same reference numerals and the description thereof need not be repeated. The difference between FIGS. 2 and 7 corresponds to the diverter 210 which will be discussed in greater detail with respect to FIGS. 8 and 9. In this embodiment, the diverter 210 includes a pad formed from a conductive material and a plurality of diversion objects that extend upwardly from the pad in a direction away from the stage 108 and towards the mold 104 (FIG. 1). The conductive pad on which the diversion objects are positioned is advantageous because it provides an easier mechanism for grounding the plurality of diversion objects as opposed to individually grounding each of the respective diversion objects. In this embodiment, a plurality of channels extending through the stage 108 (in this case, the support ring 206) are interspersed between and around the diversion objects. The diversion objects are formed from a material that has one or more of: a high conductivity, high melting point and low sputtering yield, such as tungsten and carbon (graphite). In certain embodiments, different types of diversion objects maybe included, whereby certain of the plurality of diversion objects are formed from one material (e.g. tungsten) and others of the diversion objects are formed from another material (e.g. carbon).

A more detailed view of this embodiment of the diverter 210 is shown in FIG. 8 which is in an expanded view taken from within the dashed circle labeled 702 in FIG. 7. In FIG. 8, the diverter 210 is formed from a conductive pad 802 which is grounded and thereby grounds all elements and objects in contact therewith. Extending upward from the conductive pad 802 are a plurality of diversion objects 804 which are depicted in FIG. 8 as solid filled black circles. In certain embodiments, the diversion objects 804 have a predetermined shape that improve the ability for the diversion objects 804 to attract electrostatic discharge.

More specifically, the diversion objects 804 may be individual antenna-like objects that are electrically conductive material whereby the diversion object 804 have a higher conductivity than the targeted hardware with the same distance from the superstrate (e.g. mold) or a lower distance from the charged superstrate with at least 10⁵ S/m (Siemens per meter) at 20° C. (Carbon) and is also resistant to sputtering. In one embodiment, the antenna-like diversion objects 804 are formed from Tungsten due to its low sputtering yield, high melting point, conductivity and corrosion resistance. In another embodiment, carbon is another option that provides the lowest sputtering yield available, high melting point, few gas by-products upon oxidation (CO₂), and high conductivity.

The diversion objects 804 have a predetermined shape including but not limited to cone, pyramid, rod, bar, sphere or be a ring-shape having a triangular cross section. These are exemplary in nature and are not limiting. However, the predetermined shape and size may have a tapered shape whereby its width is wider at a point of connection to the conductive pad 802 and narrows or is sharper as it extends closer to the superstrate (mold) which improves the ability to attract the electrostatic discharge. In some embodiments, the diversion objects 804 are multiple discrete points on the conductive pad 802 or may form a continuous ring, semi-circles or arcs. A height of the diversion objects 804 may be uniform. In other embodiments, the height of the discharge objects may vary and can appear serrated when viewed in cross-section. In other words, the heights of the diversion objects 804 may be two or more different heights.

Positioned adjacent to respective diversion objects are a plurality of channels 806 that extend through the stage 108 and illustrated in FIG. 8 as open circles. In one embodiment, because these channels 806 extending through the conductive pad 802, inner walls of each respective channel 806 is formed from conductive material. These channels 806 are similar in form and function as channels 604 described in FIG. 6. As such, the channels 806 should have a diameter sufficient to allow a nanoparticle sputtered from a surface due to electrostatic discharge to enter and be evacuated therefrom from a particle collection mechanism as described above. The channels 806 are exhaust ports that allow for the evacuation of nanoparticles from the imprint apparatus before they are allowed to contact any other surface.

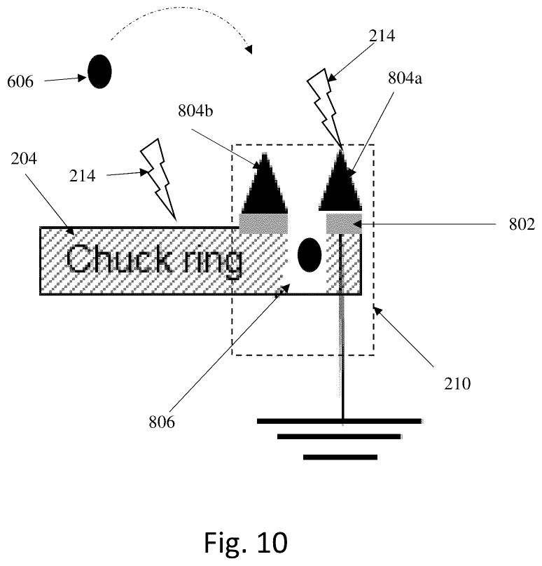

FIG. 9 is a cross-sectional view of the stage 108 taken along line labeled 9-9 in FIG. 7. This is a similar view shown in FIG. 5 and includes similar structural elements that need not be further described. In this embodiment, the diversion objects 804 extend upward from the support ring 206 in a direction towards the mold 104 and are formed in a cone shape such that an end of the diversion object 804 is narrowest (e.g. pointed) at a location closest to the mold 104. The diversion objects 804 are positioned on a grounded pad 211 thereby grounding each dispersion object positioned thereon. The channel 806 is shown positioned between two diversion objects 804 thereby allowing for an exhaust port for any nanoparticles that might be generated. An enlarged view of the diverter according to this embodiment is shown in FIG. 10.

The enlarged view of this embodiment of the diverter 210 is shown in FIG. 10. The diver 210 is positioned adjacent to the substrate support 202 (FIG. 8) and includes a conductive pad 802 (shown herein as being grounded) connected to a top surface of the support ring 204. Extending upward away from the pad 802 positioned on the support ring 204 are the plurality of diversion objects 804. As shown herein, this cross section illustrates a first diversion object 804a and a second diversion object 804b. As shown herein, the two diversion objects 804a/b are conical in shape such that a pointed tip extends up from the conductive pad 802 towards the superstrate and away from the stage. These diversion objects 804 are advantageously shaped and formed from materials that increase a likelihood to attract any errant electrostatic discharge. The diverter 210 also includes a channel 806 that extends through the support ring 206 and provides an exhaust for any nanoparticles that are produced when and if electrostatic discharge that occurs during the separation phase contacts other surfaces such as the support ring. Similarly to FIG. 6, a particle collection mechanism is provided to further aid in guiding the nanoparticle from a space between the superstrate and the substrate into the at least one channel 806 thereby removing the nanoparticle and preventing the nanoparticle from embedding into a surface of the superstrate as described above.

In another embodiment, a combination of the two above described embodiments may be included in the apparatus. For example, the diverter 210 may include both diversion objects 804 having a plurality of channels 806 interspersed therebetween and also include a diverter surface (e.g. mesh) covering the openings of each of the plurality of channels 806.

In another embodiment, the diversion objects 804 may be recessed within the support ring 204 and have a retractable cover that is controlled to open during a particular phase of the planarization process when electrostatic discharge occurs. In response to planarization monitoring being performed by the controller 128 (FIG. 1), a control signal can cause a retractable cover that covers the diversion objects 804 to move from a closed position to an open position and cause the diversion objects 804 to move in a +Z direction upward towards the mold 104 to attract the errant electrostatic discharge. In this embodiment, the signal causing the cover to open may also reveal the channel 806 extending through the support ring 204 to allow for any generated nanoparticles to travel therethrough.

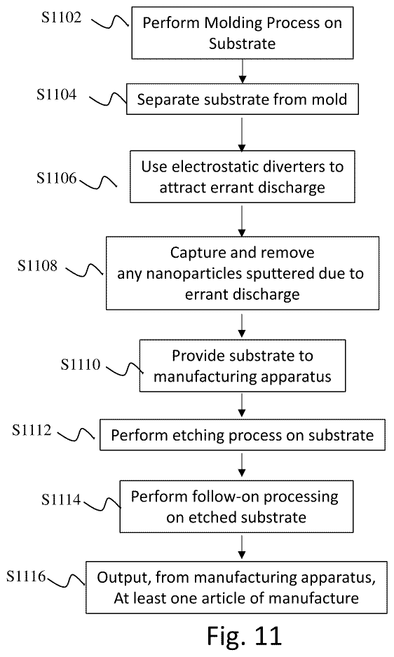

In an embodiment, after the molding process is finished additional semiconductor manufacturing processing is performed on the substrate 102 in a processing step so as to create an article of manufacture (e.g., semiconductor device). In an embodiment, each substrate includes a plurality of devices. A method detailing the manufacturing processing including the use of the diverter as described herein is illustrated in FIG. 11.

In step 1102, a substrate is loaded onto a substrate chuck and molding is performed on the substrate by bringing the pattern region into contact with liquid resist dispensed onto a surface of the substrate. In step 1104, separation processing is performed whereby the mold is separated from the substrate by and the mold moving relative to each other increasing a gap in a +Z direction, after separation the stage on which the substrate chuck is positioned and mold moving relative to each other in one of the +X direction or −X direction such that the substrate and the mold until they no longer overlap each other. This is not limiting. In certain embodiments, the stage may move in the −Z direction to separate the pattern region of the mold from the surface of the substrate. In step S1106, electrostatic discharge diverter surfaces formed from the materials described herein in the manner described herein are used to attract an errant electrostatic discharge resulting from the separation processing in S1104. In S1108, any nanoparticles that may have been generated during the separation process S1104 due to electrostatic discharge that were not attracted to the discharge surfaces of the diverter are captured and removed from the imprint environment through the at least one channel that is formed as part of the diverter according to the present disclosure. In step S1110, the substrate is provided to a manufacturing apparatus that uses the substrate to produce an article of manufacture. In an embodiment, the article of manufacture is a semiconductor device. In certain embodiments, the manufacturing apparatus may be part of the same apparatus as the molding apparatus. In other embodiments, the manufacturing apparatus may be separate. The manufacturing apparatus may include multiple distinct apparatuses. The further semiconductor manufacturing processing performed when the substrate is provided the manufacturing apparatus in S1110 includes performing, as shown in S1112 includes performing etching processes to transfer a relief image into the substrate that corresponds to the pattern in the patterned layer or an inverse of that pattern. After etching in S1112, a plurality of follow-on processing steps are performed on the etched substrate as shown in S1114. The one or more of the plurality of further processing steps include, but are not limited to, known steps and processes for article fabrication, including, for example, inspection, curing, oxidation, layer formation, deposition, doping, planarization, etching, formable material removal, dicing, bonding, packaging, mounting, circuit board assembly, and the like. The substrate may be processed to produce a plurality of articles (devices) and output form the manufacturing apparatus as shown in S1116.

A number of implementations have been described. Nevertheless, it will be understood that various modifications may be made without departing from the spirit and scope of the disclosure. Accordingly, other implementations are within the scope of the following claims.

An embodiment of the present disclosure can be carried out by providing a program implementing one or more functions of the above-described embodiment to a system or apparatus via a network or storage medium and reading and executing the program with one or more processors in a computer of the system or apparatus. Also, an embodiment of the present disclosure can be carried out by a circuit implementing one or more functions (for example, an application specific integrated circuit (ASIC)).

Embodiment(s) of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

In referring to the description, specific details are set forth in order to provide a thorough understanding of the examples disclosed. In other instances, well-known methods, procedures, components, and circuits have not been described in detail as not to unnecessarily lengthen the present disclosure.

It should be understood that if an element or part is referred herein as being “on”, “against”, “connected to”, or “coupled to” another element or part, then it may be directly on, against, connected or coupled to the other element or part, or intervening elements or parts may be present. In contrast, if an element is referred to as being “directly on”, “directly connected to”, or “directly coupled to” another element or part, then there are no intervening elements or parts present. When used, term “and/or”, includes any and all combinations of one or more of the associated listed items, if so provided.

Spatially relative terms, such as “under” “beneath”, “below”, “lower”, “above”, “upper”, “proximal”, “distal”, and the like, may be used herein for ease of description to describe one element or feature's relationship to another element(s) or feature(s) as illustrated in the various figures. It should be understood, however, that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, a relative spatial term such as “below” can encompass both an orientation of above and below. The device may be otherwise oriented (rotated 90° or at other orientations) and the spatially relative descriptors used herein are to be interpreted accordingly. Similarly, the relative spatial terms “proximal” and “distal” may also be interchangeable, where applicable.

The term “about,” as used herein means, for example, within 10%, within 5%, or less. In some embodiments, the term “about” may mean within measurement error.

The terms first, second, third, etc. may be used herein to describe various elements, components, regions, parts and/or sections. It should be understood that these elements, components, regions, parts and/or sections should not be limited by these terms. These terms have been used only to distinguish one element, component, region, part, or section from another region, part, or section. Thus, a first element, component, region, part, or section discussed below could be termed a second element, component, region, part, or section without departing from the teachings herein.

The terminology used herein is for the purpose of describing particular embodiments only and is not intended to be limiting. As used herein, the singular forms “a”, “an”, and “the”, are intended to include the plural forms as well, unless the context clearly indicates otherwise. It should be further understood that the terms “includes” and/or “including”, when used in the present specification, specify the presence of stated features, integers, steps, operations, elements, and/or components, but do not preclude the presence or addition of one or more other features, integers, steps, operations, elements, components, and/or groups thereof not explicitly stated.

The foregoing merely illustrates the principles of the disclosure. Various modifications and alterations to the described exemplary embodiments will be apparent to those skilled in the art in view of the teachings herein.

In describing example embodiments illustrated in the drawings, specific terminology is employed for the sake of clarity. However, the disclosure of this patent specification is not intended to be limited to the specific terminology so selected and it is to be understood that each specific element includes all technical equivalents that operate in a similar manner.

We claim:

1. A system comprising:
a substrate chuck;
a second chuck configured to hold an object above the substrate chuck;
one or more exhaust ports arranged adjacent to each of one or more electrostatic discharge diverter surfaces, wherein each of the one or more electrostatic discharge diverter surfaces are adjacent to the substrate chuck.

2. The system according to claim 1, wherein the electrostatic discharge diverter surfaces include a plurality of conductive peaked structures.

3. The system according to claim 1, wherein the electrostatic discharge diverter surfaces are a plurality of planar conductive surfaces surrounded by an insulated surface.

4. The system according to claim 1, wherein each of the electrostatic discharge diverter surfaces are a conductive mesh arranged above an exhaust port among the one or more exhaust ports.

5. The system according to claim 1, wherein the electrostatic discharge diverter surfaces have a melting point above 1400° C.

6. The system according to claim 1, wherein the electrostatic discharge diverter surfaces have a sputtering yield of less than 0.7 atom per 600 eV argon atom.

7. The system according to claim 1, further comprising a particle exhaust component that collects a particle generated when an electrostatic discharge event happen.

8. The system according to claim 1, wherein the one or more electrostatic discharge diverter surfaces are recessed and caused to extend upward towards the second chuck at a predetermined time.

9. A method of discharging an object comprising:
holding a substrate with a substrate chuck;
holding an object above the substrate chuck with the second chuck;
translating the substrate chuck and the second chuck relative to each other such that the second chuck passes over or more exhaust ports arranged adjacent to each of one or more electrostatic discharge diverter surfaces, wherein each of the one or more electrostatic discharge diverter surfaces are adjacent to the substrate chuck.

10. The method of claim 9 further comprising:
shaping a layer on the substrate with the object;
separating the object from the layer prior to translating the substrate chuck and the second relative to each other.

11. A method of manufacturing an article with the method of claim 9 further comprising:
processing the substrate; and
forming the article from the processed substrate.
